(19) United States
(12) Patent Application Publication
(10) Pub. No.: US 2025/0292862 A1
(43) Pub. Date: Sep. 18, 2025

(54) METHODOLOGY TO ACHIEVE TRANSACTION REDUNDANCY IN MEMORY CONSTRAINED DEVICES

(71) Applicant: XILINX, INC., San Jose, CA (US)

(72) Inventors: Krishnan SRINIVASAN, San Jose, CA (US); Yanran CHEN, San Jose, CA (US)

(21) Appl. No.: 18/608,183

(22) Filed: Mar. 18, 2024

(51) Int. Cl. G11C 29/00; G11C 29/52

(52) U.S. Cl. CPC G11C 29/76; G11C 29/52; G11C 29/785

(57) ABSTRACT

Embodiments herein describe a methodology to achieve transaction redundancy in memory-constrained devices. In an example, an initiator circuit issues an original transaction that includes a memory access request and an address of a first region of memory cells. Transaction redundancy circuitry generates a redundant transaction having an address of a second region of the memory cells (e.g., at a fixed offset from the address of the original transaction). Address transformer circuitry transforms the initial target address of the original and/or redundant transaction to ensure that a bit fault in the initial address results in an incorrect transformed address that is separated from a desired address, which will result in a data mismatch when original data and redundant data are retrieved and compared. The initial target address may be transformed based on a Hamming, SECDED, CRC, and/or other code.

### TECHNICAL FIELD

Examples of the present disclosure generally relate to a methodology to achieve transaction redundancy in memory-constrained devices.

### BACKGROUND

Systems-on-Chip (SoC) that are used in some applications, such as automotive applications, employ safety mechanisms to provide fail-safe operation and/or graceful recovery from failure. For such applications, SoCs may be designed for high-level functional safety (FuSa), which may be based on an Automotive Safety Integrity Level (ASIL) risk classification scheme defined by the International Organization for Standardization (ISO), based in Geneva, Switzerland (e.g., ISO standard 26262, titled “Functional Safety for Road Vehicles standard”).

Safety standards may be achieved with hardware mechanisms, such as lockstep hardware, or by protecting a data path with error correction codes, or by providing redundant paths for system-level communications. The foregoing approaches may not be suitable for memory subsystem safety and may not provide mixed criticality assurance in which a SoC provides a higher level of assurance to designated (e.g., critical) components/subsystems, and a lower level of assurance to other (e.g., less critical) components/subsystems.

### SUMMARY

Techniques for achieving transaction redundancy in memory-constrained devices are described. One example is an integrated circuit (IC) device that includes initiator circuitry that issues a first transaction that includes a memory access request and a first target address associated with a first region of memory cells, transaction redundancy circuitry that generates a second transaction that includes the memory access request of the first transaction and a second target address associated with a second region of the memory cells, and address transformer circuitry that transforms the second target address to a third target address associated with the second region of the memory cells (e.g., based on a Hamming code, a SECDED code, a CRC code, and/or other code).

Another example described herein is a system-on-chip (SoC) that includes a single-channel memory subsystem that includes memory cells and a memory controller that access the memory cells based on memory access requests, initiator circuitry that issues a first transaction that includes a memory access request and a first target address associated with a first region of the memory cells, transaction redundancy circuitry that generates a second transaction that includes the memory access request of the first transaction and a second target address associated with a second region of the memory cells, address transformer circuitry that transforms the second target address to a third target address associated with the second region of the memory cells, and redundant transaction management circuitry that compares read response data returned from the first region of the memory cells in response to the first transaction to read response data returned from the second region of the memory cells in response to the second transaction.

Another example described herein is an IC device that includes transaction redundancy circuitry that receives a first transaction that that includes a memory access request and a first target address associated with a first region of memory cells, and that generates a second transaction that includes the memory access request of the first transaction and a second target address associated with a second region of the memory cells, and address transformer circuitry that transforms the second target address to a third target address associated with the second region of the memory cells.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of an integrated circuit (IC) system, according to an embodiment.

FIG. 2 illustrates a method of providing transaction redundancy, according to an embodiment.

FIG. 3 is a block diagram of an IC system, according to an embodiment.

FIG. 4 illustrates a method of providing transaction redundancy, according to an embodiment.

FIG. 5 is a block diagram of a portion of the IC system of FIG. 3, according to an embodiment.

FIG. 6 is another block diagram of a portion of the IC system of FIG. 3, according to an embodiment.

FIG. 7 is another block diagram of a portion of the IC system of FIG. 3, according to an embodiment.

FIG. 8 is a block diagram of configurable circuitry, including an array of configurable or programmable circuit blocks or tiles, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe a methodology to achieve transaction redundancy in a memory-constrained device, such as a single-channel memory system.

Transaction redundancy refers to a practice of preforming redundant transactions based on original transactions, for reliability purposes. Examples are provided herein with respect to memory access transactions (e.g., memory read and/or write transactions). Transaction redundancy techniques disclosed herein are not, however, limited to memory access transactions.

Memory transaction redundancy may be useful to maintain redundant copies of data at different locations and/or on different platforms. Redundant data may be useful in one or more of a variety of contexts. Redundant data may, for example, be retrieved in the event that original data becomes corrupted or inaccessible. As another example, redundant data may compared to original data to detect data corruption and/or addressing faults.

A redundant memory transaction system may include multiple memory channels (e.g., multiple memory controllers for multiple corresponding double data rate (DDR) memory devices). An original transaction, such as a transaction related to functional safety, may be directed to a first memory channel, and a corresponding redundant transaction may be directed to a second memory channel. In this way, an address-related fault in one of the memory channels will result in a mismatch between original data and redundant data, which will indicate that a fault exists.

Where multiple memory channels are not available, an original transaction may be directed to a first address within a first region (i.e., a mission-critical region) of a single memory channel, and a corresponding redundant transaction may be directed to a second address within a second region of the single memory channel, where the second address has a fixed offset from the first address. In this situation, an address-related fault in the memory channel may equally impact the first and second addresses, which may not be detectable. As an example, if the first address is corrupted prior determining the second address, such that the second address is computed based on the corrupted first address, the original transaction will be directed to the corrupted address and the redundant transaction will be directed to a fixed offset of the corrupted address. If the transaction is a read transaction, the read response will return incorrect data, but the read data returned from original transaction and the read data returned from redundant transaction will match one another, and the fault may go undetected.

As disclosed herein, an initial target address of an original transaction and/or a redundant transaction is transformed based on a coding scheme such that, if the initial target address is free of bit-faults, the transformed target address is a desired address (i.e., an address of desired original data or desired redundant data). Whereas, if the initial target address contains a bit-fault(s), the transformed target address differs from the desired address in all, or substantially all circumstances/situations, which ensures that the original data and corresponding redundant data will not match. The mismatch may be useful to determine that a fault exists in the system.

In an example, an initial target address is transformed based on a Hamming code (e.g., an extended Hamming/SECDED code) such that, if the initial target address contains up to N bit-faults, the transformed target address will differ from the desired address by a Hamming distance of N+1. N may represent a number of bit errors that can be tolerated by a memory system. N may be determined statistically based on a probability distribution of a number of bits that can simultaneously flip. A Hamming/SECDED code ensures that up-to two bit-flips will result in a detectable error. In another example, a CRC code derived from a generator polynomial on a finite field is used.

Embodiments herein may be applied to new and/or existing integrated circuit devices.

Embodiments herein may be useful to perform localized high-level functional safety (FuSa) integrity protection and/or system-level integrity protection.

Embodiments herein may be useful to provide a mixed-criticality environment in which selected transactions are duplicated. A mixed-criticality environment may be useful to minimize overhead by applying transaction redundancy to a subset of components/subsystems (e.g., safety-critical transactions).

Embodiments herein may be useful to ensure data consistency.

Embodiments herein may be useful to detect the existence of faults.

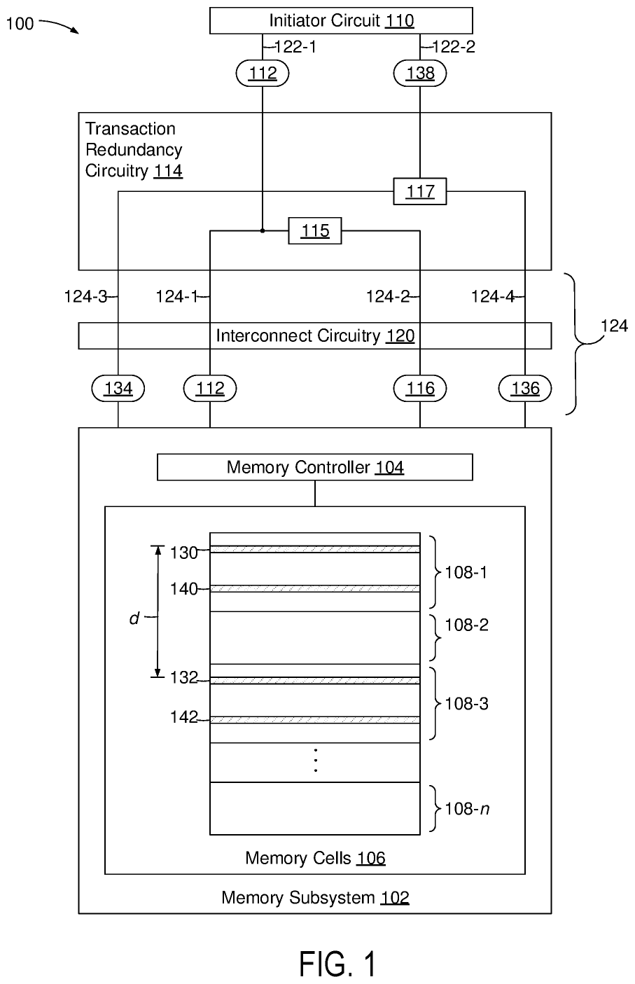

FIG. 1 is a block diagram of an integrated circuit (IC) system 100, according to an embodiment. IC system 100 includes a memory subsystem 102 that includes a memory controller 104 that accesses memory cells 106. Memory subsystem 102 may represent a single-channel memory system. Memory subsystem 102 may represent a double-data rate (DDR) memory system.

In the example of FIG. 1, memory cells 106 include regions of memory cells, illustrated here as regions 108-1 through 108-n (collectively, regions 108). Regions 108 may be represent respective ranges of consecutive addresses of memory cells 106. In an example, region 108-1 is reserved for original data (e.g., original mission-critical data), and memory region 108-3 is reserved for corresponding redundant data.

IC system 100 further includes an initiator circuit 110 that issues a transaction 112. Transaction 112 may be referred to as an original transaction. Transaction 112 may include a memory access command (e.g., a write command and/or a read command) and a target address associated with memory region 108-1.

IC system 100 further includes transaction redundancy circuitry 114 that includes redundant transaction generator circuitry 115. Redundant transaction generator circuitry 115 generates a redundant transaction 116 based on original transaction 112. Where original transaction 112 includes a read command and a target address associated with memory region 108-1, redundant transaction 116 may include the read command and a target address associated with memory region 108-3. Where original transaction 112 includes a write command, data (i.e., original data), and a target address associated with memory region 108-1, redundant transaction 116 may include the write command, a copy of the data (i.e., redundant data), and a target address associated with memory region 108-3.

Redundant transaction generator circuitry 115 may generate the target address of redundant transaction 116 based on the target address of original transaction 112. Redundant transaction generator circuitry 115 may, for example, add a fixed offset d to the target address of original transaction 112, such that the original data and the redundant data are separated by a distance defined by offset d.

Transaction redundancy circuitry 114 may further include redundant transaction management circuitry 117 that manages a response 134 to original transaction 112, and a response 136 to redundant transaction 116.

IC system 100 may selectively employ/bypass transaction redundancy circuitry 114 to provide mixed-criticality assurance in which transaction redundancy circuitry 114 is used to provide a higher level of assurance to mission-critical data, and a lower level of assurance to non-mission-critical data. IC system 100 may selectively employ/bypass transaction redundancy circuitry 114 based on, for example and without limitation, the target address of original transaction 112, and identifier associated with original transaction 112, and/or a privilege level associated with initiator circuit 110.

Although memory subsystem 102 may represent a single-channel memory system, IC system 100 may include multiple communication paths between initiator circuit 110 and memory subsystem 102. In the example of FIG. 1, IC system 100 includes a communication path 122 between initiator circuit 110 and transaction redundancy circuitry 114. Communication path 122 may represent a single communication path (e.g., a bi-directional path) or multiple communication paths (e.g., separate transmit and receive channels). For illustrative purposes, communication path 122 is illustrated in FIG. 1 as including a communication path 122-1 for original transaction 112 and a communication path 122-1 for response 138 to original transaction 112.

IC system 100 further includes a communication path 124 between transaction redundancy circuitry 114 and memory subsystem 102. Communication path 124 may represent a single communication path or multiple communication paths. For illustrative purposes, communication path 124 is illustrated in FIG. 1 as including a communication path 124-1 for original transaction 112, a communication path 124-2 for redundant transaction 116, a communication path 124-3 for response 134 to original transaction 112, and a communication path 124-4 for response 136 to redundant transaction 116. In practice, communication path 124-1 and 124-2 may be implemented as a single path, multiple independent paths, and/or overlapping paths.

Communication path 124 may include interconnect circuitry 120, which may include, without limitation, buffers, a packet-switched network such as a network-on-a-chip (NoC), and/or point-to-point interconnect circuitry, which may conform to a point-to-point protocol such as, without limitation, an Advanced eXtensible interface (AXI) on-chip communication bus protocol developed by ARM of Cambridge, England.

IC system 100 may include additional initiator circuits, and may further include additional transaction redundancy circuitry 114.

IC system 100 may include and/or represent one or more IC devices (e.g., dies or packages), and may be part of a system-on-chip (SoC). For example, and without limitation, memory subsystem 102, initiator circuit 110, transaction redundancy circuitry 114, and/or interconnect circuitry 120, may reside on a single IC device or may be distributed amongst multiple IC devices of IC system 100.

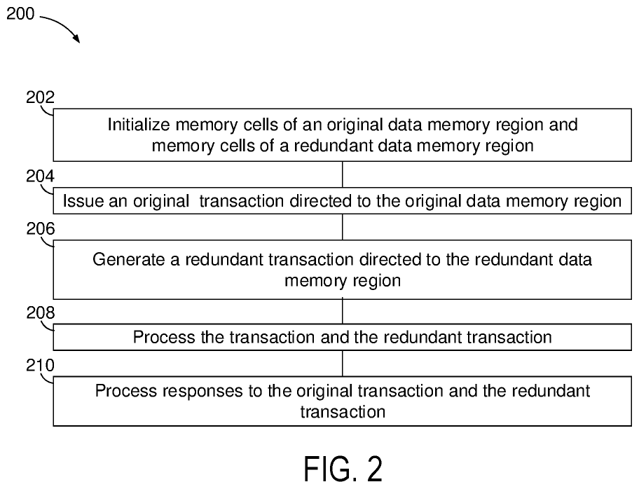

FIG. 2 illustrates a method 200 of providing transaction redundancy, according to an embodiment. Method 200 is described below with reference to IC system 100. Method 200 is not, however, limited to the example of IC system 100.

At 202, a controller of IC system (e.g., memory controller 104) may initialize memory cells 106 of regions 108-1 and 108-3, such that contents of memory cells of region 108-1 match contents of corresponding memory cells of region 108-3. The controller may initialize the memory cells to contain all zeros or all ones.

At 204, initiator circuit 110 initiates original transaction 112. In a first example (i.e., a write example), original transaction 112 includes a write request, data, and a target address 130 of region 108-1. In a second example (i.e., a read example), original transaction 112 includes a read request and target address 130.

At 206, redundant transaction generator circuitry 115 generates redundant transaction 116 based on original transaction 112. For the write example, redundant transaction 116 includes the write request and a copy of the data of original transaction 112, and further includes a target address 132 of memory region 108-3 (e.g., having a fixed offset from target address 130 of original transaction 112). For the read example, redundant transaction 116 includes the read request of original transaction 112 and target address 132.

Redundant transaction generator circuitry 115 may assign identifiers (IDs) to original transaction 112 and redundant transaction 116. Alternatively, interconnect circuitry 120 and/or other circuitry may assign an ID (e.g., system management identifiers (SIDs) or AXIDs), to original transaction 112, and transaction redundancy circuitry 114 may assign an ID to redundant transaction 116 based on the ID assigned to original transaction 112. Redundant transaction generator circuitry 115 may, for example, add a bit to an ID of original transaction 112 to provide the ID for redundant transaction 116. The added bit may be introduced as a most significant bit of the ID of original transaction 112. A SID may be programmed across multiple redundant transactions across multiple splitters. Redundant transaction management circuitry 117 may use the IDs to manage response 134 to original transaction 112 and response 136 to redundant transaction 116. Alternatively, or additionally, memory controller 104 may use the IDs to control access to memory regions 108-1 and 108-3.

At 208, memory subsystem 102 processes original transaction 112 and redundant transaction 116, and returns corresponding responses 134 and 136. For the write example, memory subsystem 102 writes the original data of transaction 112 to target address 130, and writes the redundant data of redundant transaction 116 to target address 132. Memory subsystem 102 may return corresponding write acknowledgements in responses 134 and 136, indicating whether the original data and the redundant data were successfully written to target addresses 130 and 132.

For the read example, memory subsystem 102 returns original data from target address 130 in response 134 and returns redundant data from target address 132 in response 136. Memory subsystem 102 may also return read acknowledgments indicating whether the original data and the redundant data were successfully read from target addresses 130 and 132.

At 210, redundant transaction management circuitry 117 and/or other circuitry processes responses 134 and 136. For the write example, if responses 134 and 136 indicate that the original data and the redundant data were successfully written to addresses 130 and 132, redundant transaction management circuitry 117 may report the successes to initiator circuit 110 in a response 138. If response 134 and/or response 136 indicates that the original data and/or the redundant data were not successfully written to addresses 130 and 132, redundant transaction management circuitry 117 may generate an error indication, which may include an interrupt and/or other control.

For the read example, redundant transaction management circuitry 117 may compare the original data and the redundant data returned in responses 134 and 136. If the original data and the redundant data match, transaction redundancy circuitry 114 may forward the original data and/or the redundant data to initiator circuit 110 in response 138. If the original data and the redundant data do not match, transaction redundancy circuitry 114 may re-send original transaction 112 and/or redundant transaction 116 to memory subsystem 102. Alternatively, redundant transaction management circuitry 117 may generate an error indication.

A mismatch between the original data and the redundant data returned in responses 134 and 136 may occur if a bit-fault (i.e., a bit-flip) arises in the target address of original transaction 112 and/or in the target address of redundant transaction 116, between transaction redundancy circuitry 114 and memory cells 106. As an example, if a bit-flip arises in the target address of redundant transaction 116, and the bit-flip changes the target address from address 132 to an address 142, the data returned in response 136 from address 142 will likely not match the data returned from address 130. In this situation, redundant transaction management circuitry 117 will detect the mismatch.

As another example, if a bit-flip arises in the target address of original transaction 112, subsequent to generation of redundant transaction 116, and the bit-flip changes the target address to an address 140, the data returned in response 134 from address 140 will likely not match the data returned from address 132. In this situation, redundant transaction management circuitry 117 will detect the mismatch.

If, however, a bit-flip arises in the target address of original transaction 112 prior to generation of redundant transaction 116, and the bit-flip changes the original target address to address 140, for example, redundant transaction generator circuitry 115 will generate the target address of redundant transaction 116 based on address 140. In this situation, memory subsystem 102 will return data from addresses 140 and 142. Assuming that the data at addresses 140 and 142 were properly written (i.e., during initialization at 202 or during a subsequent write operation), redundant transaction management circuitry 117 will not detect a mismatch and will return the data from address 140 and/or address 142 to initiator circuit 110. In other words, redundant transaction management circuitry 117 may not detect an address fault (e.g., a single-bit address fault) that arises in the target address of original transaction 112 between initiator circuit 110 and transaction redundancy circuitry 114. Methods and systems to address such a situation are provided further below. Methods and systems described below may be useful to detect address faults that arise at any point between initiator circuit 110 and memory cells 106.

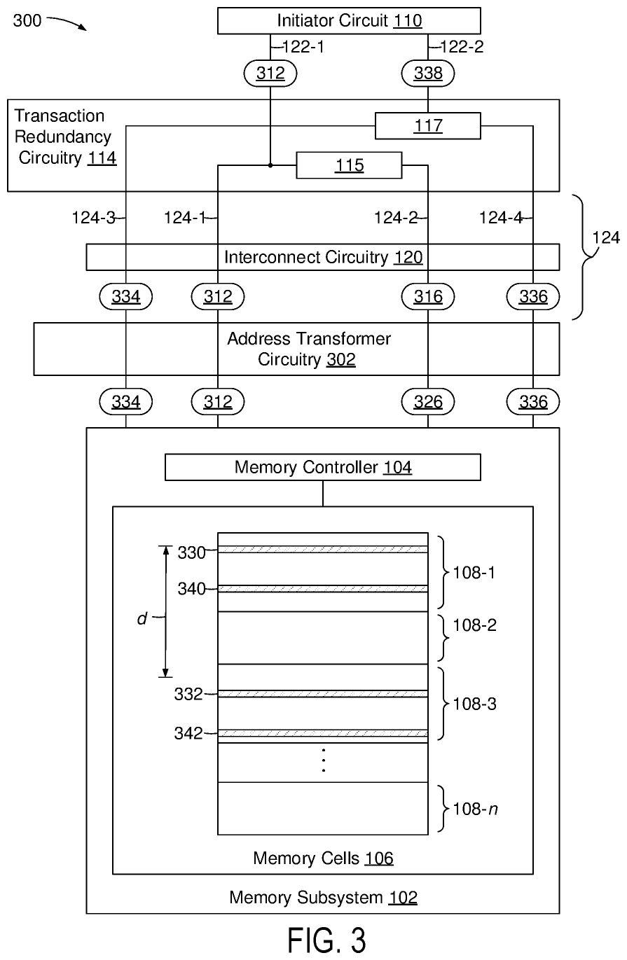

FIG. 3 is a block diagram of an IC system 300, according to an embodiment. IC system 300 includes features described above with reference to FIG. 1, and further includes address transformer circuitry 302 that transforms the target address of original transaction 112 and/or the target address of redundant transaction 116.

IC system 300 may selectively employ/bypass transaction redundancy circuitry 114 and/or address transformer circuitry 302 to provide mixed-criticality assurance in which transaction redundancy circuitry 114 and address transformer circuitry 302 are used to provide a higher level of assurance to mission-critical data, and a lower level of assurance to non-mission-critical data. IC system 100 may selectively employ/bypass transaction redundancy circuitry 114 and/or address transformer circuitry 302 based on target addresses, IDs, and/or privilege levels, such as described further above with reference to FIG. 1.

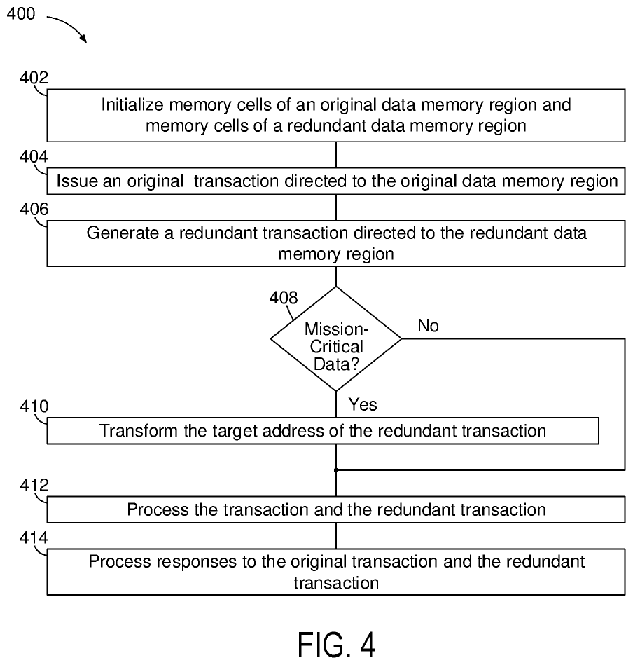

FIG. 4 illustrates a method 400 of providing transaction redundancy, according to an embodiment. Method 400 is described below with reference to IC system 300. Method 400 is not, however, limited to the example of IC system 300.

At 402, a controller of IC system (e.g., memory controller 104) may initialize memory cells 106 of regions 108-1 and 108-3, such as described above with reference to 202 in FIG. 2.

At 404, initiator circuit 110 initiates original transaction 312. In a write example, original transaction 312 includes a write request, original data, and a target address 330 of memory region 108-1. In a read example, original transaction 312 includes a read request and target address 330.

At 406, redundant transaction generator circuitry 115 generates redundant transaction 316 based on original transaction 312. For the write example, redundant transaction 316 includes the write request and a copy of the original data of original transaction 312, and further includes an initial target address 332 of memory region 108-3. For the read example, redundant transaction 316 includes the read command of original transaction 312 and target address 132.

Redundant transaction generator circuitry 115 and/or other circuitry may assign an ID to original transaction 312 and/or to redundant transaction 316, such as described further above.

At 410, address transformer circuitry 302 transforms the target address of original transaction 312 and/or the target address of redundant transaction 316. Address transformer circuitry 302 may transform the target address such that, if the target address is free of bit-faults, the resultant transformed target address is a desired address (i.e., an address that contains desired original data or desired redundant data). Whereas, if the target address contains a bit-fault(s), the resultant transformed target address differs from the desired address in all, or substantially all circumstances/situations, which ensures that the original data and corresponding redundant data will not match.

For illustrative purposes, address transformation is described below for an example in which address transformer circuitry 302 transforms the target address of redundant transaction 316. In FIG. 3, the address-transformed redundant transaction is illustrated as redundant transaction 326.

In an example, address transformer circuitry 302 transforms the initial target address of redundant transaction 316 (i.e., the target address assigned by transaction redundancy circuitry 114) such that, if the initial target address is free of bit-faults, the resultant target address of redundant transaction 326 corresponds to an address 332 (i.e., a desired address) of memory region 108-3. Whereas, if the initial target address contains a bit-fault, the resultant target address of redundant transaction 326 corresponds to an address 342 of memory region 108-3, where a distance between addresses 332 and 342 is at least N+1, and N is a number of the bit-faults in the initial target address of redundant transaction 316. IC system 300, or a portion thereof (e.g., memory subsystem 102), may be designed to tolerate up to N bit-errors in target addresses. N may be determined statistically from a probability distribution of the number of bits that can simultaneously flip.

In an example, address transformer circuitry 302 embeds a codeword in the initial target address of redundant transaction 316 to provide the target address of redundant transaction 326 such that a bit-flip in the initial target address of redundant transaction 316 will result in an incorrect target address of redundant transaction 326.

Address transformer circuitry 302 may embed the codeword based on a Hamming code, such as an extended Hamming code. Hamming codes are a family of linear error-correcting codes. Hamming codes can used for detecting one-bit and two-bit errors, or to correct one-bit errors without detection of uncorrected errors. In other words, Hamming codes have a minimum distance of 3, which means that a decoder can detect and correct a single error, but cannot distinguish a double bit error of one codeword from a single bit error of another codeword. Extended Hamming codes include an extra parity bit to provide a Hamming distance of four, which allows a decoder to distinguish between when at most one one-bit error occurs and when any two-bit errors occur. Extended Hamming codes are essentially single-error correcting and double-error detecting (SECDED) codes.

A SECDED code may ensure that a two-bit error is detected by the codeword. This implies that a single-bit or double-bit error in the original address will point to an address in the redundant space that is not at the same offset. In other words, a two-bit flip in the original address will manifest as 3 bit-flips in the target address of redundant transaction 326, thus ensuring that the in the target address of redundant transaction 326 does not the correct redundant address for original transaction 312.

A Hamming or SECDED code may be selected based on a desired Hamming distance between the target addresses of redundant transactions 316 and 326. A Hamming or SECDED code may be selected to provide a Hamming distance of at least N+1 between the target addresses of redundant transactions 316 and 326, such that a fault that affects at most N bits in the target address of redundant transaction 316 can be effectively accounted for. In other words, up to N errors can occur at the same time, with assurance that the target address of redundant transaction 326 is at least (N+1) bits away from the initial target address of redundant transaction 316.

As another example, address transformer circuitry 302 may embed a codeword based on a cyclic redundancy check (CRC) code derived from a generator polynomial on a finite field. Such a CRC code may be useful to provide a comprehensive coding scheme that can detect multiple bit errors, N>2 (e.g., up to 4 bit-flips, or more). Address transformer circuitry 302 is not, however, limited to Hamming codes, SECDED codes, or CRC codes.

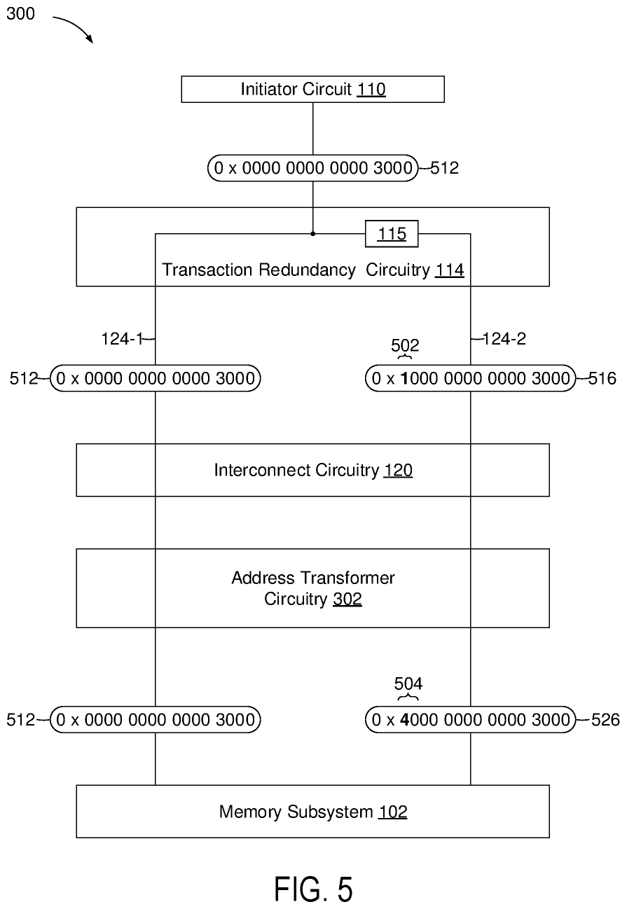

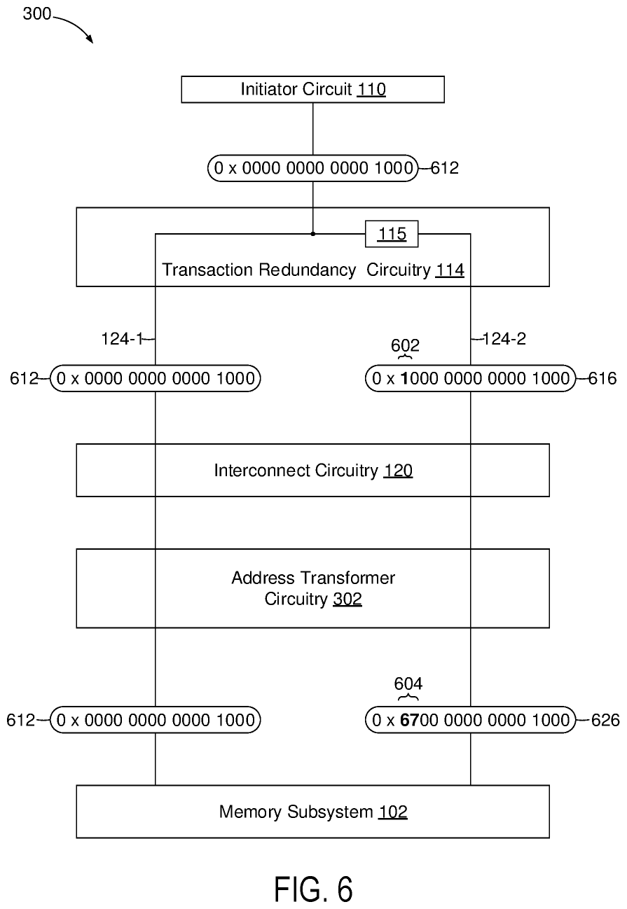

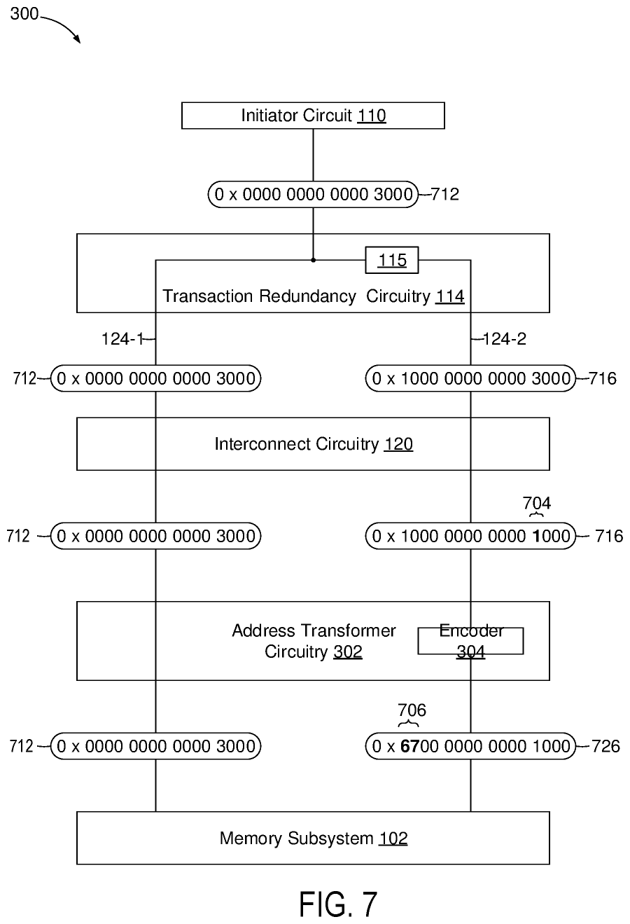

Examples are provided further below with reference to FIGS. 5, 6, and 7, in which address transformer circuitry 302 inserts one or more bits in a target address based on a Hamming code. Address transformer circuitry 302 may generate the bits dynamically based on the target address of the redundant transaction 316. Alternatively, address transformer circuitry 302 may retrieve the bits from a look-up table based on the target address of the redundant transaction 316. FIGS. 5 and 6 illustrate examples in which target addresses of original transaction 312 and redundant transaction 316 are free of bit faults. FIG. 7 illustrates an example in which an initial target address of a redundant transaction contains a bit fault.

At 412, memory subsystem 102 processes original transaction 312 and redundant transaction 326, and returns corresponding responses 334 and 336. In the write example, memory subsystem 102 writes the original data of transaction 312 to target address 330, and writes the redundant data of redundant transaction 326 to address 332. Memory subsystem 102 may return corresponding write acknowledgements in responses 334 and 336, indicating whether the original data and the redundant data were successfully written to addresses 330 and 332.

In the read example, memory subsystem 102 returns data from address 330 in response 334, and returns data from address 332 in response 336. Memory subsystem 102 may also return read acknowledgments in responses 334 and 336 indicating whether the data was successfully read from addresses 330 and 332.

At 412, redundant transaction management circuitry 117 and/or other circuitry processes responses 334 and 336. In the write example, if responses 334 and 336 indicate that the original data and the redundant data were successfully written to addresses 330 and 332, redundant transaction management circuitry 117 may report the successful operations to initiator circuit 110 in a response 338. If response 334 and/or response 336 indicates that the data was not successfully written to address 330 and/or address 332, redundant transaction management circuitry 117 may generate an error indication, which may include an interrupt and/or other control.

In the read example, redundant transaction management circuitry 117 may compare the data returned in responses 334 and 336. If the data matches, redundant transaction management circuitry 117 may forward the data returned in response 334 and/or 336 to initiator circuit 110 in response 338. If the data does not match, redundant transaction management circuitry 117 may re-send original transaction 312 and/or redundant transaction 316 to address transformer circuitry 302. Alternatively, redundant transaction management circuitry 117 may generate an error indication.

Additional examples are provided below with reference to FIGS. 5, 6, and 7. FIGS. 5 and 6 illustrate examples in which target addresses of original transaction 312 and redundant transaction 316 are free of bit faults. FIG. 7 illustrates an example in which initial target address redundant transaction 316 contains a bit fault.

FIG. 5 is a block diagram of a portion of IC system 300, according to an embodiment. In the example of FIG. 5, initiator circuit 110 initiates an original transaction 512 with a target address 0x0000 0000 0000 3000. Transaction redundancy circuitry 114 generates a corresponding redundant transaction 516 with a target address 0x1000 0000 0000 3000. In this example, transaction redundancy circuitry 114 applies an offset 0x1000 0000 0000 0000, as illustrated by a bit 502 of the target address of redundant transaction 516. Address transformer circuitry 302 transforms the target address of redundant transaction 516 to provide a redundant transaction 526 having a target address 0x4000 0000 3000. In this example, address transformer circuitry 302 replaced upper address bits 504 of redundant transaction 516 with 8-bits of SECDED code. The SECDED code for 0x4000 is 0x40 hexadecimal, or 0100 0000 binary, in a 127-120 coding scheme. In this example, address 0x0000 0000 0000 3000 contains original data and address 0x4000 0000 3000 contains corresponding redundant data.

FIG. 6 is a block diagram of a portion of IC system 300, according to an embodiment. In the example of FIG. 6, initiator circuit 110 initiates an original transaction 612 with a target address 0x0000 0000 0000 1000. Transaction redundancy circuitry 114 generates a corresponding redundant transaction 616 with a target address 0x1000 0000 0000 1000. In this example, transaction redundancy circuitry 114 applies the offset 0x1000 0000 0000 0000, as illustrated by a bit 602 of the target address of redundant transaction 616. Address transformer circuitry 302 transforms the target address of redundant transaction 616 to provide a redundant transaction 626 having a target address 0x6700 0000 1000. In this example, address transformer circuitry 302 replaced upper address bits 604 of redundant transaction 616 with 8-bits of SECDED code. The SECDED code for 0x1000 is 0x67 hexadecimal, 0110 0111 binary, in a 127-120 coding scheme. In this example, address 0x0000 0000 0000 1000 contains original data and address 0x6700 0000 1000 contains corresponding redundant data.

FIG. 7 is a block diagram of a portion of IC system 300, according to an embodiment. In the example of FIG. 7, initiator circuit 110 initiates an original transaction 712 with a target address 0x0000 0000 0000 3000, and transaction redundancy circuitry 114 generates a corresponding redundant transaction 716 with a target address 0x1000 0000 0000 3000, as in the example of FIG. 6.

In the example of FIG. 7, a bit-flip 704 arises in the target address of redundant transaction 716, prior to address transformation. In this example, a target address 0x1000 0000 0000 1000 is presented to address transformer circuitry 302, rather than the target address 0x1000 0000 0000 3000. Address transformer circuitry 302 thus transforms address 0x1000 0000 0000 1000 to provide a redundant transaction 726 having a target address 0x6700 0000 1000. The SECDED code for 0x1 000 is 0x67 hexadecimal, 0110 0111 binary in a 127-120 coding scheme, as described above with reference to FIG. 7. In this example, memory controller 104 perform a memory transaction (e.g., a read or write command) with respect to address 0x1000 0000 0000 3000 of original transaction 712 and the corrupted address 0x6700 0000 1000 of redundant transaction 726. However, as illustrated in the example of FIG. 6, the correct target address for redundant transaction 726 is 0x4000 0000 3000. For a read operation, redundant transaction management circuitry 117 will detect a data mismatch.

In the foregoing examples, the target address of original transaction 312 may be referred to as a first target address, the initial target address of redundant transaction 316, may be referred to as a second target address, and the transformed target address of redundant transaction 326 may be referred to as a third target address.

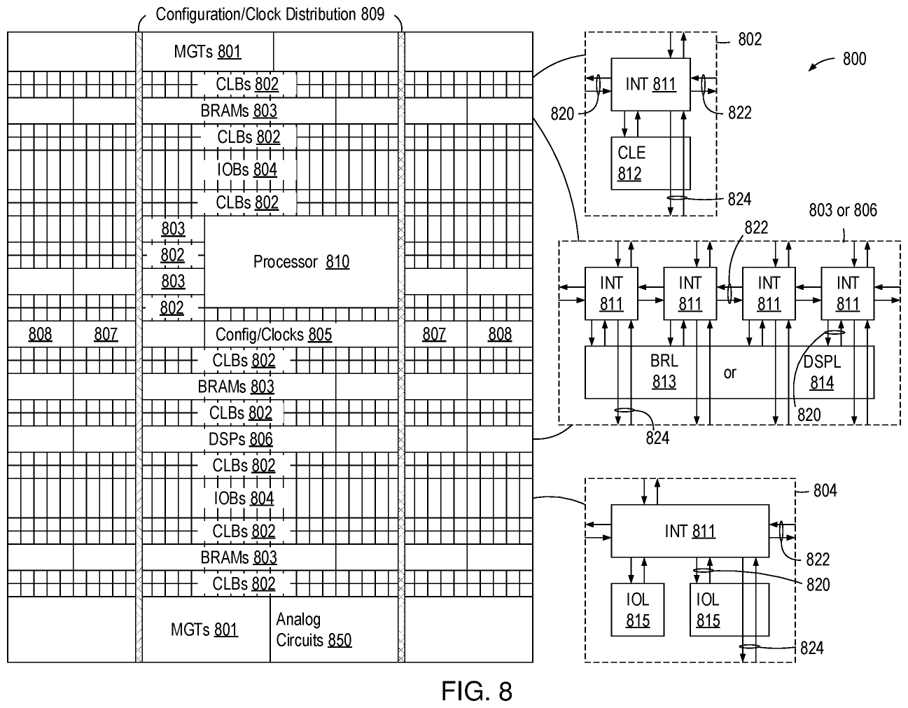

IC system 100 and/or IC system 300, or a portion thereof, may include one or more of a variety of types of configurable circuit blocks, such as described below with reference to FIG. 8. FIG. 8 is a block diagram of configurable circuitry 800, including an array of configurable or programmable circuit blocks or tiles, according to an embodiment. The example of FIG. 8 may represent a field programmable gate array (FPGA) and/or other IC device(s) that utilizes configurable interconnect structures for selectively coupling circuitry/logic elements, such as complex programmable logic devices (CPLDs).

In the example of FIG. 8, the tiles include multi-gigabit transceivers (MGTs) 801, configurable logic blocks (CLBs) 802, block random access memory (BRAM) 803, input/output blocks (IOBs) 804, configuration and clocking logic (Config/Clocks) 805, digital signal processing (DSP) blocks 806, specialized input/output blocks (I/O) 807 (e.g., configuration ports and clock ports), and other programmable logic 808, which may include, without limitation, digital clock managers, analog-to-digital converters, and/or system monitoring logic. The tiles further includes a dedicated processor 810.

One or more tiles may include a programmable interconnect element (INT) 811 having connections to input and output terminals 820 of a programmable logic element within the same tile and/or to one or more other tiles. A programmable INT 811 may include connections to interconnect segments 822 of another programmable INT 811 in the same tile and/or another tile(s). A programmable INT 811 may include connections to interconnect segments 824 of general routing resources between logic blocks (not shown). The general routing resources may include routing channels between logic blocks (not shown) including tracks of interconnect segments (e.g., interconnect segments 824) and switch blocks (not shown) for connecting interconnect segments. Interconnect segments of general routing resources (e.g., interconnect segments 824) may span one or more logic blocks. Programmable INTs 811, in combination with general routing resources, may represent a programmable interconnect structure.

A CLB 802 may include a configurable logic element (CLE) 812 that can be programmed to implement user logic. A CLB 802 may also include a programmable INT 811.

A BRAM 803 may include a BRAM logic element (BRL) 813 and one or more programmable INTs 811. A number of interconnect elements included in a tile may depends on a height of the tile. A BRAM 803 may, for example, have a height of five CLBs 802. Other numbers (e.g., four) may also be used.

A DSP block 806 may include a DSP logic element (DSPL) 814 in addition to one or more programmable INTs 811. An IOB 804 may include, for example, two instances of an input/output logic element (IOL) 815 in addition to one or more instances of a programmable INT 811. An I/O pad connected to, for example, an I/O logic element 815, is not necessarily confined to an area of the I/O logic element 815.

In the example of FIG. 8, config/clocks 805 may be used for configuration, clock, and/or other control logic. Vertical columns 809 may be used to distribute clocks and/or configuration signals.

A logic block (e.g., programmable of fixed-function) may disrupt a columnar structure of configurable circuitry 800. For example, processor 810 spans several columns of CLBs 802 and BRAMs 803. Processor 810 may include one or more of a variety of components such as, without limitation, a single microprocessor to a complete programmable processing system of microprocessor(s), memory controllers, and/or peripherals.

In FIG. 8, configurable circuitry 800 further includes analog circuits 850, which may include, without limitation, one or more analog switches, multiplexers, and/or de-multiplexers. Analog switches may be useful to reduce leakage current.

FIG. 8 is provided for illustrative purposes. Configurable circuitry 800 is not limited to numbers of logic blocks in a row, relative widths of the rows, numbers and orderings of rows, types of logic blocks included in the rows, relative sizes of the logic blocks, illustrated interconnect/logic implementations, or other example features of FIG. 8.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC) device, comprising:
initiator circuitry configured to issue a first transaction that comprises a memory access request and a first target address associated with a first region of memory cells;
transaction redundancy circuitry configured to generate a second transaction that comprises the memory access request of the first transaction and a second target address associated with a second region of the memory cells; and
address transformer circuitry configured to transform the second target address of the second transaction to a third target address associated with the second region of the memory cells.

2. The IC device of claim 1, wherein the address transformer circuitry is further configured to:
determine a codeword based on the second target address; and
embed the codeword in the second target address to provide the third target address.

3. The IC device of claim 1, wherein:
the address transformer circuitry is further configured to transform the second target address to the third target address based on the second target address and a Hamming code.

4. The IC device of claim 1, wherein:
the address transformer circuitry is further configured to transform the second target address to the third target address based on the second target address and an extended Hamming code.

5. The IC device of claim 1, wherein:
the address transformer circuitry is further configured to transform the second target address to the third target address based on the second target address and a cyclic redundancy check (CRC) code derived from a generator polynomial on a finite field.

6. The IC device of claim 1, wherein the address transformer circuitry is further configured to transform the second target address to the third target address such that:
the third target address corresponds to a first address of the second region of the memory cells if the second target address is free of bit-faults; and
the third target address corresponds to a second address of the second region of the memory cells if the second target address comprises one or more bit-faults;
wherein a distance between the first and second addresses is at least N+1;
wherein Nis a number of the bit-faults in the second target address; and
wherein N is a positive integer.

7. The IC device of claim 1, wherein:
the transaction redundancy circuitry is further configured to determine the second target address based on the first target address and a fixed offset.

8. The IC device of claim 1, wherein:
the memory access request comprises a write request
the first transaction further comprises write data; and
the transaction redundancy circuitry is further configured to generate the second transaction to include the write request and the write data.

9. The IC device of claim 1, wherein the memory access request comprises a read request, further comprising:
redundant transaction management circuitry configured to compare read response data returned from the first region of the memory cells in response to the first transaction, to read response data returned from the second region of the memory cells in response to the second transaction.

10. The IC device of claim 1, further comprising:
a memory system comprising the memory cells and a memory controller configured to access the memory cells, including to perform the memory access request of the first transaction with respect to the first target address of the first region of the memory cells and to perform the memory access request of the second transaction with respect to the third target address of the second region of the memory cells.

11. A system-on-chip (SoC), comprising:
a single-channel memory subsystem comprising memory cells and a memory controller configured to access the memory cells based on memory access requests;
initiator circuitry configured to issue a first transaction that comprises a memory access request and a first target address associated with a first region of the memory cells;
transaction redundancy circuitry configured to generate a second transaction that comprises the memory access request of the first transaction and a second target address associated with a second region of the memory cells;
address transformer circuitry configured to transform the second target address of the second transaction to a third target address associated with the second region of the memory cells; and
redundant transaction management circuitry configured to compare read response data returned from the first region of the memory cells in response to the first transaction, to read response data returned from the second region of the memory cells in response to the second transaction.

12. The SoC of claim 11, wherein the address transformer circuitry is further configured to transform the second target address such that:
the third target address corresponds to a first address of the second region of the memory cells if the second target address is free of bit-faults; and
the third target address corresponds to a second address of the second region of the memory cells if the second target address comprises one or more bit-faults;
wherein a distance between the first and second addresses is at least N+1;
wherein Nis a number of the bit-faults in the second target address; and
wherein N is a positive integer.

13. The SoC of claim 11, wherein:
the address transformer circuitry is further configured to determine a codeword based on the second target address; and
embed the codeword in the second target address to provide the third target address.

14. The SoC of claim 13, wherein the codeword is based on one or more of:
a Hamming code;
an extended Hamming code; and
a cyclic redundancy check (CRC) code derived from a generator polynomial on a finite field.

15. The SoC of claim 13, wherein address transformer circuitry is further configured to compute the codeword based on the second target address.

16. The SoC of claim 13, wherein address transformer circuitry is further configured to look-up the codeword based on the second target address.

17. The SoC of claim 11, wherein the transaction redundancy circuitry is further configured to selectively generate the second transaction based on one or more of:
the first target address;
an identifier associated the first transaction; and
a privilege level associated with the initiator circuitry.

18. The SoC of claim 11, wherein the address transformer circuitry is further configured to selectively generate the second transaction based on one or more of:
the first target address;
an identifier associated the first transaction;
a privilege level associated with the initiator circuitry; and
the second target address.

19. An integrated circuit (IC) device, comprising:
transaction redundancy circuitry configured to receive a first transaction that comprises a memory access request and a first target address associated with a first region of memory cells, and to generate a second transaction that comprises the memory access request of the first transaction and a second target address associated with a second region of the memory cells; and
address transformer circuitry configured to transform the second target address of the second transaction to a third target address associated with the second region of the memory cells.

20. The IC device of claim 19, wherein the address transformer circuitry is further configured to transform the second target address to the third target address such that:
the third target address corresponds to a first address of the second region of the memory cells if the second target address is free of bit-faults; and
the third target address corresponds to a second address of the second region of the memory cells if the second target address comprises one or more bit-faults;
wherein a distance between the first and second addresses is at least N+1;
wherein Nis a number of the bit-faults in the second target address; and
wherein N is a positive integer.
